(19) United States
(12) Patent Application Publication
(10) Pub. No.: US 2024/0154047 A1
(43) Pub. Date: May 9, 2024

(54) Light Receiving Element and Manufacturing Method Therefor

(71) Applicant: Nippon Telegraph and Telephone Corporation, Tokyo (JP)

(72) Inventors: Yoshiho Maeda, Musashino-shi, Tokyo (JP); Toru Segawa, Musashino-shi, Tokyo (JP)

(21) Appl. No.: 18/549,839

(22) PCT Filed: Apr. 13, 2021
(86) PCT No.: PCT/JP2021/015289

§ 371 Date: Sep. 8, 2023

(51) Int. Cl. H01L 31/0224; H01L 31/105; H01L 31/18; H01L 31/0304

(52) U.S. Cl. CPC H01L 31/022408; H01L 31/105; H01L 31/1844; H01L 31/03046

(57) ABSTRACT

A semiconductor layer is formed on a substrate, and is formed with a semiconductor. The semiconductor can be, for example, a group III-V compound semiconductor. Further, in the semiconductor layer, a p-type p-region, an i-type i-region, and an n-type n-region, which form a pin junction in a planar direction of the substrate, are formed. A light absorbing layer is formed on the p-region of the semiconductor layer, and is formed with a p-type semiconductor. A contact layer is formed on the light absorbing layer, and is formed with a p-type semiconductor.

### TECHNICAL FIELD

The present invention relates to a light receiving element and a method for manufacturing a light receiving element.

### BACKGROUND ART

As an ultrahigh-speed and high-sensitivity light receiving element for an optical transceiver, a uni-traveling-carrier (UTC) photodiode (PD) has been proposed (Non Patent Literature 1). Generally, an operation band of the PD is determined by a carrier travelling time and a CR time constant. For this reason, it is important to minimize both the carrier travelling time and the CR time constant in improving a speed of the PD.

In the UTC-PD, a p-type semiconductor is used as a light absorbing layer, and a travelling time of electrons generated by the light absorbing is a dominant factor for improving a speed in an operation band. Further, the UTC-PD is designed to minimize the electron travelling time by using an electron velocity overshoot effect by precisely controlling a doping profile of a p-type semiconductor stack structure on an order of several tens of nanometers.

On the other hand, from a viewpoint of high sensitivity, it is known that a waveguide-type PD in which a stack direction of semiconductor layers for forming an element, that is, a carrier transport direction is orthogonal to a light propagation direction is advantageous in achieving both high speed and high sensitivity.

In order to shorten the carrier traveling time, it is important to form a depletion layer to be thinner. However, in this case, the CR time constant increases due to thinning of the depletion layer. For this reason, in order to improve a speed of the waveguide-type PD, it is very important to decrease the CR time constant.

For example, as the waveguide-type PD, a structure illustrated in FIG. 3A and FIG. 3B has been proposed. The PD includes an InP substrate 301, an n-InP layer 302, an i-InP layer 303, a p-InGaAs absorbing layer 304, a p-InGaAsP diffusion barrier layer 305, a p-InGaAs contact layer 306, an n-electrode 307, and a p-electrode 308. The n-InP layer 302 is formed on the InP substrate 301. A mesa is formed by the i-InP layer 303, the p-InGaAs absorbing layer 304, the p-InGaAsP diffusion barrier layer 305, and the p-InGaAs contact layer 306, and the mesa is formed on the n-InP layer 302. In addition, the n-electrode 307 is formed on the n-InP layer 302 around the mesa, and the p-electrode 308 is formed on the p-InGaAs contact layer 306.

The PD is a waveguide-type UTC-PD that includes a vertical-type pin junction obtained by forming a pin junction by the n-InP layer 302, the i-InP layer 303, and the p-InGaAs absorbing layer 304 which are stacked and includes an optical waveguide in which the i-InP layer 303 corresponds to a core. In the UTC-PD, in order to decrease the CR time constant while maintaining a light receiving sensitivity, it is desirable to decrease a width T′ of the depletion layer (a width of the i-InP layer 303). Note that, in FIG. 3A, W ′_{dep} is a thickness of the i-InP layer 303.

However, in the UTC-PD, in a case where the width T′ of the depletion layer is decreased, a width of the mesa is decreased, and as a result, areas of the p-InGaAs contact layer 306 and the n-electrode 307 are reduced. For this reason, in the UTC-PD, in a case where the width T′ of the depletion layer is decreased, a contact resistance is inversely increased, and as a result, an effect of decreasing the CR time constant is small.

As a structure capable of preventing an increase in the contact resistance and decreasing the CR time constant as compared with the UTC-PD including the above-described vertical-type pin junction, as illustrated in Non Patent Literature 2, there is a waveguide-type PD including a so-called horizontal-type pin junction in which a pin junction is formed in a planar direction of the substrate that is orthogonal to the semiconductor stack direction.

In the waveguide-type PD including the horizontal-type pin junction, an area of the depletion layer and areas of the contact layer and the electrode can be independently determined. Thus, it is possible to decrease the area of the depletion layer, that is, it is possible to decrease the CR time constant.

However, the horizontal-type pin junction is formed by known ion implantation, impurity diffusion, or crystal regrowth. For this reason, it is difficult to implement a precise doping profile or a hetero-structure on an order of several tens of nanometers as in the vertical-type pin junction.

### CITATION LIST

### Non Patent Literature

Non Patent Literature 1: T. Ishibashi and H. Ito, “Uni-traveling-carrier photodiodes”, Journal of Applied Physics, vol. 127, 031101, 2020.
Non Patent Literature 2: Y. Baumgartner et al., “CMOS-Compatible Hybrid III-V/Si Photodiodes Using a Lateral Current Collection Scheme”, European Conference on Optical Communication, 18265198, 2018.

### SUMMARY OF INVENTION

### Technical Problem

As described above, in the technique in the related art, for a waveguide-type PD expected to have a high speed and a high sensitivity, a hetero-junction structure including an impurity profile on an order of several tens of nanometers is adopted. As a result, there is a problem that it is difficult to minimize the electron traveling time while preventing an increase in the contact resistance due to a reduction of the depletion layer.

The present invention has been made to solve the above problems, and an object of the present invention is, in a waveguide-type photodiode, to minimize an electron traveling time by preventing an increase in the contact resistance due to a reduction of the depletion layer.

### Solution to Problem

According to the present invention, there is provided a light receiving element including: a semiconductor layer that is formed on a substrate and is formed with a semiconductor; a p-type p-region, an i-type i-region, and an n-type n-region that are formed in the semiconductor layer and form a pin junction in a planar direction of the substrate; a light absorbing layer that is formed on the p-region of the semiconductor layer and is formed with a p-type semiconductor;

a contact layer that is formed on the light absorbing layer and is formed with a p-type semiconductor; a p-electrode that is formed to be electrically connected to the contact layer; and an n-electrode that is formed to be electrically connected to the n-region of the semiconductor layer.

According to the present invention, there is provided a method for manufacturing a light receiving element, the method including: a first step of forming, on a substrate, a semiconductor layer formed with a semiconductor; a second step of forming, on the semiconductor layer, a light absorbing layer formed with a p-type semiconductor and a contact layer formed with a p-type semiconductor; a third step of forming a p-type p-region in the semiconductor layer under the light absorbing layer; a fourth step of forming, in the semiconductor layer, an i-type i-region and an n-type n-region that form a pin junction together with the p-region in a planar direction of the substrate; and a fifth step of forming a p-electrode that is electrically connected to the contact layer and an electrode that is electrically connected to the n-region of the semiconductor layer.

### Advantageous Effects of Invention

As described above, according to the present invention, the pin junction is formed in the semiconductor layer in the planar direction of the substrate, and the light absorbing layer, the contact layer, and the p-electrode are stacked on the p-region. Therefore, in a waveguide-type photodiode, it is possible to prevent an increase in the contact resistance due to a reduction of the depletion layer, and thus it is possible to minimize an electron traveling time.

### BRIEF DESCRIPTION OF DRAWINGS

FIG. 1A is a cross-sectional view illustrating a configuration of a light receiving element according to an embodiment of the present invention.

FIG. 1B is a planar view illustrating a configuration of the light receiving element according to the embodiment of the present invention.

FIG. 2A is a cross-sectional view illustrating a state of the light receiving element in an intermediate step to explain a method for manufacturing the light receiving element according to the embodiment of the present invention.

FIG. 2B is a cross-sectional view illustrating a state of the light receiving element in an intermediate step to explain a method for manufacturing the light receiving element according to the embodiment of the present invention.

FIG. 2C is a cross-sectional view illustrating a state of the light receiving element in an intermediate step to explain a method for manufacturing the light receiving element according to the embodiment of the present invention.

FIG. 2D is a cross-sectional view illustrating a state of the light receiving element in an intermediate step to explain a method for manufacturing the light receiving element according to the embodiment of the present invention.

FIG. 2E is a cross-sectional view illustrating a state of the light receiving element in an intermediate step to explain a method for manufacturing the light receiving element according to the embodiment of the present invention.

FIG. 3A is a cross-sectional view illustrating a configuration of a waveguide-type photodiode.

FIG. 3B is a planar view illustrating a configuration of the waveguide-type photodiode.

### DESCRIPTION OF EMBODIMENTS

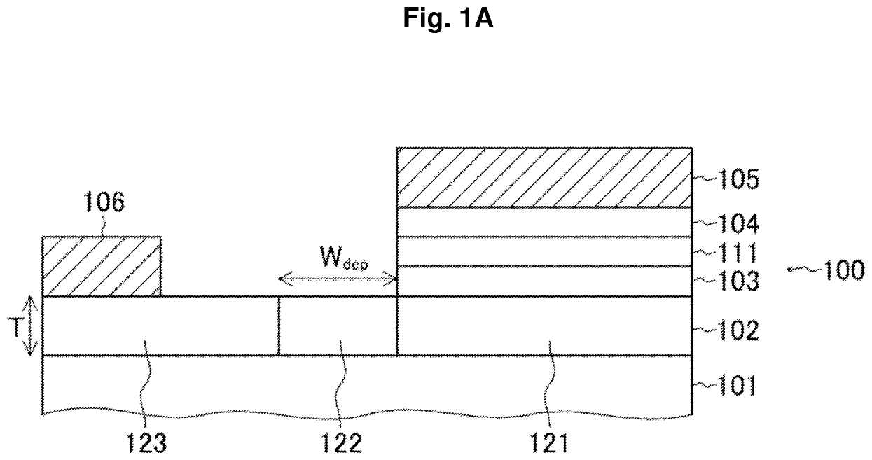

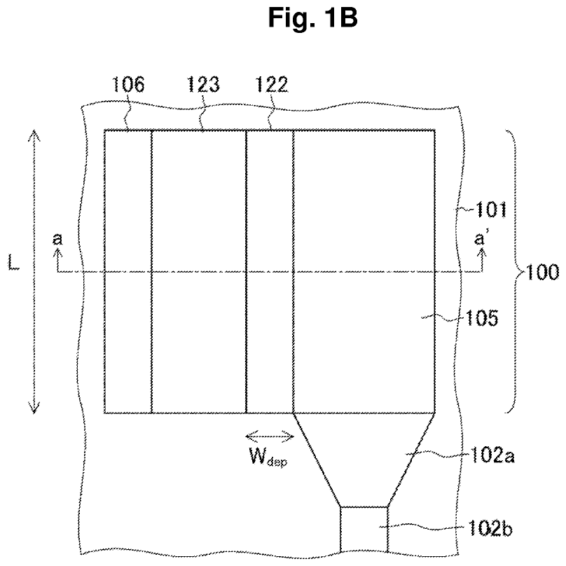

Hereinafter, a light receiving element 100 according to an embodiment of the present invention will be described with reference to FIG. 1A and FIG. 1B. FIG. 1A illustrates a cross-section taken along a line aa′ of FIG. 1B.

The light receiving element 100 includes a substrate 101, a semiconductor layer 102, a light absorbing layer 103, and a contact layer 104. The substrate 101 is formed with, for example, semi-insulating InP. The semiconductor layer 102 is formed on the substrate 101, and is formed with a semiconductor. The semiconductor can be, for example, a group III-V compound semiconductor. The semiconductor layer 102 is formed with, for example, InP. Further, in the semiconductor layer 102, a p-type p-region 121, an i-type i-region 122, and an n-type n-region 123, which form a pin junction in a planar direction of the substrate 101, are formed.

Here, the light receiving element 100 is a so-called waveguide-type photodiode in which the p-region 121 mainly corresponds to a core. A waveguide direction of the light receiving element 100 having an optical waveguide structure in which the p-region 121 corresponds to a core is a direction from behind to in front of a paper surface of FIG. 1A, and is a vertical direction of a paper surface of FIG. 1B. FIG. 1A illustrates a cross-section perpendicular to the waveguide direction of the light receiving element 100.

A core 102b that forms an optical waveguide is disposed outside the light receiving element 100. A spot size conversion structure 102a is formed between the core 102b and the p-region 121, and optically connects the light receiving element 100, which has an optical waveguide structure in which the p-region 121 corresponds to a core, and the optical waveguide formed by the core 102b.

The light absorbing layer 103 is formed on the p-region 121 of the semiconductor layer 102, and is formed with a p-type semiconductor. The light absorbing layer 103 is formed with, for example, p-type InGaAs (p-InGaAs). The contact layer 104 is formed on the light absorbing layer 103, and is formed with a p-type semiconductor. The contact layer 104 is formed with, for example, p-type InGaAs (p-InGaAs).

Further, in the embodiment, a diffusion barrier layer 111, which is formed between the light absorbing layer 103 and the contact layer 104 and is formed with a semiconductor having a bandgap larger than a bandgap of the light absorbing layer 103, is provided. The diffusion barrier layer 111 is formed with, for example, p-type InGaAsP (p-InGaAsP).

Here, a composition of InGaAs for forming the light absorbing layer 103 can be set, for example, within a range in which it has a sensitivity to light in a communication wavelength band (1310 nm to 1550 nm). On the other hand, a composition of InGaAsP for forming the diffusion barrier layer 111 can be set within a range in which it does not have a sensitivity to light in the communication wavelength band (1310 nm to 1550 nm).

In addition, the light receiving element 100 includes a p-electrode 105 electrically connected to the contact layer 104 and an n-electrode 106 electrically connected to the n-region 123 of the semiconductor layer 102. Each of the electrodes can be formed with, for example, Au. Here, it is important that the contact layer 104 and the n-region 123 are doped to a sufficiently high concentration of approximately 1×10¹⁹ cm⁻³ or higher so as to obtain an ohmic contact (connection) between the p-electrode 105 and the n-electrode 106 which are formed with metal. Note that the above-described semiconductor can be formed with a group IV element such as Si or Ge.

In the embodiment, the light absorbing layer 103, the diffusion barrier layer 111, the contact layer 104, and the n-electrode 106 have a mesa structure which has a predetermined width in a direction perpendicular to the waveguide direction and perpendicular to a stack direction (a planar direction of a surface of the substrate 101) and has a predetermined length L in the waveguide direction. The i-region 122 and the n-region 123 are formed in the semiconductor layer 102 which extends in a direction perpendicular to the waveguide direction from a position of the mesa structure in a plane parallel to the plane of the substrate 101. The width of the mesa structure is set to a width in a range in which the light receiving element 100 functions as an optical waveguide photodiode, that is, a range in which a propagation mode exists in the optical waveguide in which the p-region 121 mainly corresponds to a core.

In a case where light is entered (introduced) into the light receiving element 100 according to the embodiment via the optical waveguide formed by the core 102b, the entered light is mainly guided into the p-region 121 of the semiconductor layer 102, and is absorbed by the light absorbing layer 103. As the light is absorbed by the light absorbing layer 103, electron-hole pairs are generated in the light absorbing layer 103. The holes in the electron-hole pairs generated in the light absorbing layer 103 in this manner are dielectrically relaxed in a very short time in the light absorbing layer 103.

On the other hand, the electrons in the electron-hole pairs generated in the light absorbing layer 103 as described above are diffused toward a direction of the p-region 121 and a direction of the diffusion barrier layer 111 according to an impurity concentration gradient and a carrier density distribution. Here, since the diffusion barrier layer 111 has a band gap larger than a band gap of the light absorbing layer 103, the diffusion barrier layer 111 functions as a diffusion barrier for the electrons. Thus, the electrons generated in the light absorbing layer 103 are mainly diffused toward the direction of the p-region 121.

The electrons diffused in the p-region 121 are accelerated by an internal electric field of the horizontal-type pin junction formed by the p-region 121, the i-region 122, and the n-region 123. In a case where the electrons are drifted and reach the n-region 123, the electrons form a photoelectric current. As described above, the light receiving element 100 according to the embodiment functions as UTC-PD as described in Non Patent Literature 1. In the light receiving element 100, a capacitance between the p-region 121 and the n-region 123 is determined by a distance between the p-region 121 and the n-region 123 and an area of the i-region 122 in a cross-section perpendicular to the direction of the pin junction. Therefore, as L and T increase, the capacitance between the p-region 121 and the n-region 123 increases. On the other hand, as the distance between the p-region 121 and the n-region 123 increases, the capacitance decreases.

Hereinafter, a capacitance C_{L} and a resistance R of the light receiving element 100 according to the embodiment will be described. In a case where the p-region 121 has a sufficiently high concentration, a capacitance C_{L} of a depletion layer formed in the i-region 122 is determined by the following Equation (1). Note that W_{dep} is a width of the depletion layer in the horizontal-type pin junction and is a distance between the p-region 121 and the n-region 123. Further, ε is a dielectric constant of the depletion layer (the i-region 122). On the other hand, assuming that a contact area with the contact layer 104 is S_{CL}, and a contact resistivity is ρ_{CL}, a contact resistance R_{C} of the n-electrode 106 is expressed by the following Equation (2).

$$\begin{matrix}[ Equation 1 ] & \\ {C}_{L} = ε \frac{L \cdot T}{{W}_{dep}} & ( 1 ) \\ {R}_{c} = \frac{{ρ}_{CL}}{{S}_{CL}} & ( 2 )\end{matrix}$$

Therefore, assuming that a load resistance is R_{L}, a CR time constant is expressed by the following Equation (3).

$$\begin{matrix}[ Equation 2 ] & \\ CR = {C}_{L} \cdot {R}_{c} = ( ε \frac{L \cdot T}{{W}_{dep}} ) \cdot ( {R}_{L} + \frac{{ρ}_{CL}}{{S}_{cL}} ) & ( 3 )\end{matrix}$$

As described above, even in a case where the width W_{dep} of the depletion layer is narrowed in order to decrease the capacitance C, W_{dep} and S_{cL} are independent from each other, the contact resistance R_{cL} does not increase.

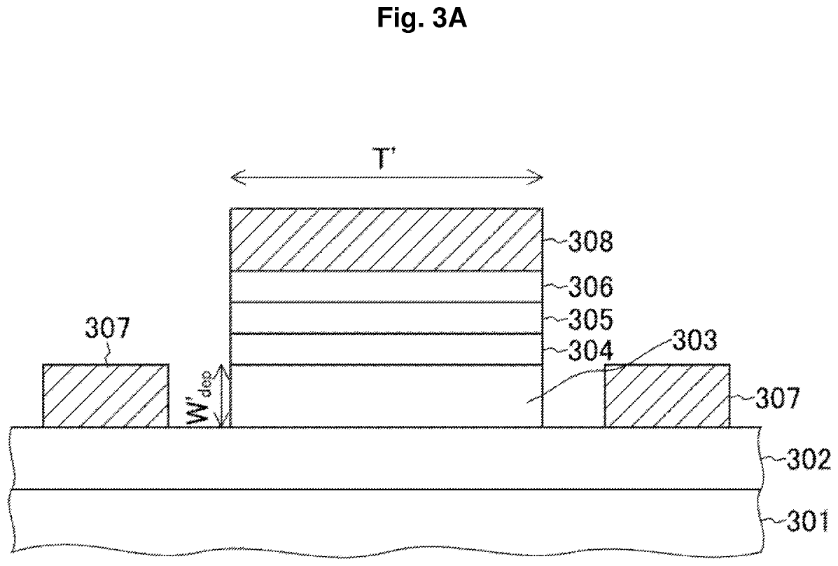

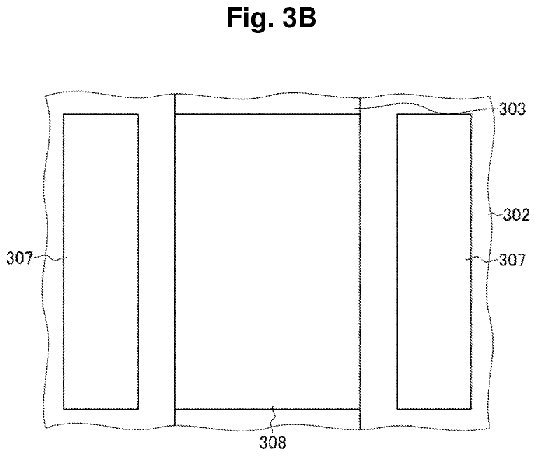

On the other hand, in the waveguide-type photodiode in the related art that has been described with reference to FIG. 3A and FIG. 3B and uses a vertical-type pin junction obtained by manufacturing a pin junction in a stack direction of the semiconductor, a capacitance Cᵥ of the depletion layer is expressed by the following Equation. Note that, in Equation (4), W′_{dep} is a distance between the n-InP layer 302 and the p-InGaAs absorbing layer 304. In other words, W′_{dep} is a thickness of the i-InP layer 303.

$$\begin{matrix}[ Equation 3 ] & \\ {C}_{V} = ( ε \frac{L \cdot {T}^{′}}{{W}_{dep}^{′}} ) & ( 4 )\end{matrix}$$

Further, a width of the p-InGaAs contact layer is narrower than a width T′ of the depletion layer due to the stacked structure. Therefore, assuming that an area of the contact layer is S_{CV}, the contact resistance R_{CV} is expressed by the following Equation (5), and the CR time constant is expressed by the following Equation (6).

$$\begin{matrix}[ Equation 4 ] & \\ {R}_{CV} = \frac{{ρ}_{cV}}{{S}_{CV}} \geq \frac{{ρ}_{cV}}{L \cdot {T}^{′}} & ( 5 ) \\ CR = {C}_{V} \cdot {R}_{CV} \geq ( ε \frac{L \cdot {T}^{′}}{{W}_{dep}^{′}} ) \cdot ( {R}_{L} + \frac{{ρ}_{cv}}{L \cdot {T}^{′}} ) & ( 6 )\end{matrix}$$

Here, it can be seen that, in the waveguide-type photodiode in the related art, in a case where the width T′ of the depletion layer is narrowed in order to decrease the capacitance C, this leads to an increase in the contact resistance R_{CV}. Further, assuming that S_{CL}>>S_{CV}, “C_{L}·R_{CL}<<C_{V}·R_{CV}” is obtained. Thereby, it can be seen that the structure of the light receiving element 100 according to the embodiment is effective in decreasing the CR time constant.

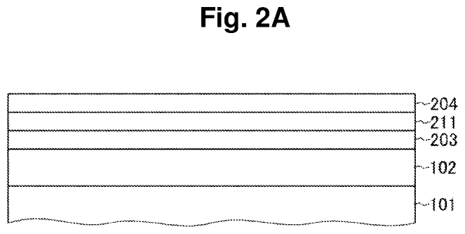

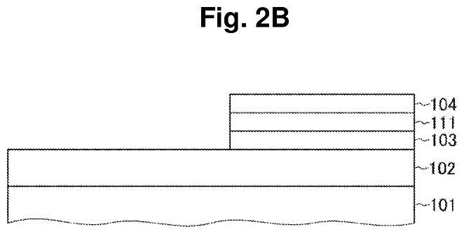

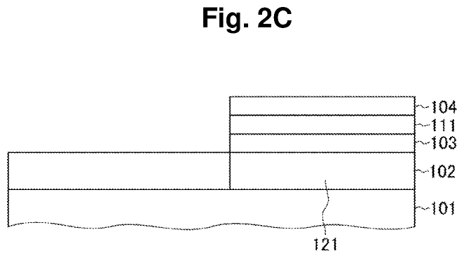

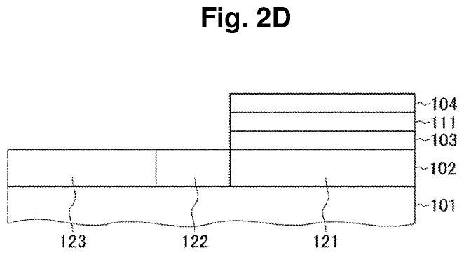

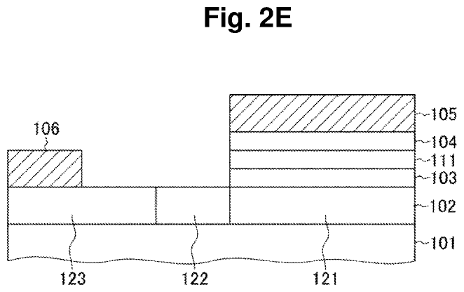

Next, a method for manufacturing the light receiving element 100 according to the embodiment of the present invention will be described with reference to FIG. 2A to FIG. 2E.

First, as illustrated in FIG. 2A, a semiconductor layer 102 formed with i-InP is formed on a substrate 101 (first step). In addition, a p-InGaAs layer 203, a p-InGaAsP layer 211, and a p-InGaAs layer 204 are formed on the semiconductor layer 102. The p-InGaAs layer 203 is a layer serving as the light absorbing layer 103. The p-InGaAsP layer 211 is a layer serving as the diffusion barrier layer 111. Further, the p-InGaAs layer 204 is a layer serving as the contact layer 104.

Each of these layers can be formed, for example, by growth using a known epitaxial crystal growth technique (MO-CVD method, MBE method, or the like). In addition, a doping concentration of impurities in each semiconductor layer is controlled by using an in-situ doping technique in a process of epitaxial crystal growth.

Next, as illustrated in FIG. 2B, a mesa structure including the light absorbing layer 103, the diffusion barrier layer 111, and the contact layer 104 is formed by patterning the p-InGaAs layer 203, the p-InGaAsP layer 211, and the p-InGaAs layer 204 using a known photolithography technique and a known etching technique (second step). In the patterning, at the same time, an optical waveguide structure for light incidence such as the spot size conversion structure 102a and the core 102b is formed in another region of the semiconductor layer 102.

Next, as illustrated in FIG. 2C, a p-region 121 is formed in the semiconductor layer 102 under the light absorbing layer 103 (third step). For example, a p-region 121 can be formed by selectively introducing p-type impurities into a predetermined region of the semiconductor layer 102 by using an impurity diffusion technique. Note that an ion implantation technique can also be used.

Next, as illustrated in FIG. 2D, an i-type i-region 122 and an n-type n-region 123, which form a pin junction together with the p-region 121 in the planar direction of the substrate, are formed in the semiconductor layer 102 (fourth step). For example, an n-region 123 can be formed by selectively introducing n-type impurities into a predetermined region of the semiconductor layer 102 by using an ion implantation technique. By forming an n-region 123 apart from the p-region 121, an i-region 122 can be formed between the p-region 121 and the n-region 123.

Thereafter, as illustrated in FIG. 2E, a p-electrode 105 and an n-electrode 106 are formed (fifth step). For example, a mask layer having an opening in each electrode formation region is formed, and a metal film is formed on the mask layer by a known metal vapor deposition technique. Thereafter, the mask layer is lifted off, and thus the p-electrode 105 and the n-electrode 106 are formed. In addition, the p-electrode 105 and the n-electrode 106 can also be formed by forming a metal film by a metal vapor deposition technique and then patterning the formed metal film by a known photolithography technique and a known etching technique.

As described above, according to the present invention, the pin junction is formed in the semiconductor layer in the planar direction of the substrate, and the light absorbing layer, the contact layer, and the p-electrode are stacked on the p-region. Therefore, in the waveguide-type photodiode, it is possible to prevent an increase in the contact resistance due to a reduction of the depletion layer, and thus it is possible to minimize an electron traveling time.

Note that the present invention is not limited to the embodiment described above, and it is obvious that many modifications and combinations can be made by those skilled in the art without departing from the scope of the present invention.

### REFERENCE SIGNS LIST

100 Light receiving element
101 Substrate
102 Semiconductor layer
102a Spot size conversion structure
102b Core
103 Light absorbing layer
104 Contact layer
105 P-electrode
106 N-electrode
111 Diffusion barrier layer
121 P-region
122 I-region
123 N-region

1. A light receiving element comprising:
a semiconductor layer that is formed on a substrate and is formed with a semiconductor;
a p-type p-region, an i-type i-region, and an n-type n-region that are formed in the semiconductor layer and form a pin junction in a planar direction of the substrate;
a light absorbing layer that is formed on the p-region of the semiconductor layer and is formed with a p-type semiconductor;
a contact layer that is formed on the light absorbing layer and is formed with a p-type semiconductor;
a p-electrode that is formed to be electrically connected to the contact layer; and
an n-electrode that is formed to be electrically connected to the n-region of the semiconductor layer.

2. The light receiving element according to claim 1, further comprising:
a diffusion barrier layer that is formed between the light absorbing layer and the contact layer and is formed with a semiconductor having a band gap larger than a band gap of the light absorbing layer.

3. The light receiving element according to claim 1,
wherein the semiconductor is formed with a group IV element.

4. The light receiving element according to claim 1,
wherein the semiconductor is a group III-V compound semiconductor.

5. A method for manufacturing a light receiving element, the method comprising:
a first step of forming, on a substrate, a semiconductor layer formed with a semiconductor;
a second step of forming, on the semiconductor layer, a light absorbing layer formed with a p-type semiconductor and a contact layer formed with a p-type semiconductor;
a third step of forming a p-type p-region in the semiconductor layer under the light absorbing layer;
a fourth step of forming, in the semiconductor layer, an i-type i-region and an n-type n-region that form a pin junction together with the p-region in a planar direction of the substrate; and
a fifth step of forming a p-electrode that is electrically connected to the contact layer and an electrode that is electrically connected to the n-region of the semiconductor layer.

6. The light receiving element according to claim 2,
wherein the semiconductor is formed with a group IV element.

7. The light receiving element according to claim 2,
wherein the semiconductor is a group III-V compound semiconductor.
